(19) United States
(12) Patent Application Publication
(10) Pub. No.: US 2018/0201776 A1
(43) Pub. Date: Jul. 19, 2018

(54) EPOXY RESIN COMPOSITION FOR COPPER CLAD LAMINATE, AND APPLICATION OF EPOXY RESIN COMPOSITION

(71) Applicant: Shengyi Technology Co., Ltd., Guandong (CN)

(72) Inventors: Ying XU, Guangdong (CN); Kehong FANG, Guangdong (CN)

(73) Assignee: Shengyi Technology Co.,Ltd., Guangdong (CN)

(21) Appl. No.: 15/744,005

(22) PCT Filed: Dec. 7, 2015
(86) PCT No.: PCT/CN2015/096519

§ 371 Date: Jan. 11, 2018

(30) Foreign Application Priority Data
Aug. 3, 2015 (CN) 201510483470.2

(51) Int. Cl. C08L 63/00; C08J 5/24; C08G 59/50; C08G 59/30; C08G 59/38; B32B 5/26; B32B 5/02; B32B 15/14; B32B 15/20; H05K 1/03

(52) U.S. Cl. CPC C08L 63/00; H05K 2201/012; C08G 59/5033; C08G 59/308; C08G 59/304; C08G 59/38; B32B 5/26; B32B 5/022; B32B 5/024; B32B 15/14; B32B 15/20; H05K 1/0373; C08L 2205/025; C08L 2205/03; C08J 2363/02; C08J 2463/02; C08L 2201/02; B32B 2260/021; B32B 2260/046; B32B 2262/101; B32B 2307/306; B32B 2457/08; C08J 5/24

(57) ABSTRACT

The present invention relates to an epoxy resin composition for a copper clad laminate, and an application of the epoxy resin composition. The epoxy resin composition may be used for the preparation of pre-pregs and copper clad laminates. By using brominated epoxy resin such as a low bromine epoxy resin and a high bromine epoxy resin as bromine sources and taking a phosphorus-containing phenanthrene-type compound as a phosphorus source, and adjusting the proportions of the brominated epoxy resins and the phosphorus-containing phenanthrene-type compound within the epoxy resin composition, the bromine content is controlled at 5-12%, the phosphorus content is controlled at 0.2-1.5%, and the flame retardancy achieves the level of UL94 V-0. Compared to pure bromine flame retardant copper clad laminates, the heat resistance is higher, and a higher CTI value is achieved. Compared to pure phosphorus flame retardant copper clad laminates, the moisture absorption is low, and the adhesion performance and process operability required for printed circuit substrates are provided. Compared to the use of a large amount of aluminum hydroxide in traditional high CTI sheet material, the present invention achieves CTI>600V using a small amount of aluminum hydroxide or without using aluminium hydroxide.

### TECHNICAL FIELD

The present invention relates to the technical field of laminates, specifically to an epoxy resin composition, especially to an epoxy resin composition for copper clad laminates, as well as a prepreg, a laminate and a printed circuit board prepared therefrom.

### BACKGROUND ART

With the formal implementations of the EU directives of WEEE (Waste Electrical and Electronic Equipment) and RoHS (Restriction of Hazardous Substances), the global electronics industry has entered a lead-free soldering era. The increase of lead-free soldering temperature puts forward higher requirements on the heat resistance and thermal stability of copper clad laminates for printed circuits. Affected by the “green” regulations issued by the European Union, it has been pushed to the front line of controversy whether bromine as a flame retardant element should be used in the field of polymers. Although tetrabromobisphenol A, as a flame retardant, has not been found to have any significant negative impact on the environment, the voice of making it a prohibited substance is increasingly higher. Therefore, the flame retardant dependence on bromine in the future will be necessarily and gradually reduced. It is even more urgent to find a technology of copper clad laminates having better heat resistance, low moisture absorption and less dependence on bromine.

Bromine is mostly used for flame retardancy in traditional FR4. Bromine has a high flame retardant efficiency, and flame retardant substances such as tetrabromobisphenol A are inexpensive and easy to be popularized. However, the total bromine content in ordinary FR4 needs to typically reach 15% or higher (the mass ratio of bromine to the organic solids in the plates) so as to achieve UL94V-0 level, if only bromine is used for flame retardancy. Higher bromine content is not only contrary to the environment-friendliness, but also lead to a serious decline in the heat resistance of the material itself because C—Br bond is easy to break. Organic matters with high bromine contents are not conducive to work under high temperature and pressure, in wet and easily contaminated environment, since bromine will accelerate the leakage failure of materials between the two circuits of circuit boards. Thus, the materials can be made to adapt to harsh surroundings, such as high pressure and humidity and the like by reducing the bromine content. For example, both CN101654004A and CN102382420A disclose that, starting from epoxy resins and fillers, the use of epoxy resin containing a bromine content which is reduced to 10-15% in the resin system or specially modified, and the addition of a large amount of inorganic fillers, such as aluminum hydroxide, makes the materials adapt to harsh environments. However, a too large amount of aluminum hydroxide will decrease the heat resistance. This is because aluminum hydroxide has a low thermal decomposition temperature and starts to dehydrate at 200° C.; the PCB soldering temperature ranges from 245-260° C., which easily makes the final plates have delamination and blistering at high temperature, so as to affect the reliability of the products.

Phosphorus flame retardants can also achieve the purpose of flame retardancy. Since the phosphorus flame retardant system contains no bromine, it has a much better heat resistance than the bromine flame retardant system. However, phosphorus is easy to absorb moisture. The plates merely using phosphorus element for flame retardancy have a higher moisture absorption, which is not conducive to the electrical property stability of the plates. At present, phosphorus-based flame retardants generally have higher price and higher cost pressure. Therefore, it is not possible to discard brominated flame retardants for cost reasons, although there is a high voice for halogen-free flame retardants. CN102093670A discloses a process for achieving flame retardancy by using a phosphorus-containing phenolic aldehyde containing 9,10-dihydro-9-oxa-10-phosphaphenanthrene-10-oxide (DOPO) structure. Although DOPO has a lower water absorption than phosphate, the moisture absorption rate thereof has not been better improved since the phosphorus content is also above 2% due to its large amount.

Although both CN101892027 and CN101808466 disclose using bromine and phosphorus together, they reveal using much nitrile rubber. As compared to epoxy resin, the acrylonitrile structure has a higher water absorption, and the composite substrate has a reduced voltage resistance. In addition, the acrylonitrile structure in nitrile rubber will speed up the decomposition of bromine, and thus be not good for the CTI performance of the bromine-containing system. However, not all of the phosphorus sources and bromine sources used in the above two patents are connected to the polymer backbone. Moreover, rubbers have an adverse effect on Tg. Thus a higher glass transition temperature is hard to be achieved in said above two patents,

Therefore, it is an urgent problem to be solved to find an epoxy resin composition having a low moisture absorption, a high comparative tracking index (CTI) value, and having good heat resistance, cohesiveness, reactivity, and processability.

### DISCLOSURE OF THE INVENTION

The object of the present invention lies in providing an epoxy resin composition, especially an epoxy resin composition for copper clad laminates, as well as a prepreg, a laminate and a printed circuit board prepared therefrom.

In order to achieve the object, the present invention discloses the following technical solutions.

In the first aspect, the present invention provides an epoxy resin composition comprising, based on the weight parts of organic solids,

(A) from 50 to 100 parts by weight of a mixture of phosphorus-containing epoxy resin, bromine-containing epoxy resin and other epoxy resin,
(B) from 1 to 50 parts by weight of a curing agent,
(C) from 0.05 to 1.0 part by weight of a curing accelerator,
wherein the bromine in the epoxy resin composition is in an amount of 5-12% of the weight sum of organic solids in the composition; the phosphorus in the epoxy resin composition is in an amount of 0.2-1.5% of the weight sum of organic solids in the composition.

In the current production of CCL, bromine-containing flame retardant materials, when used alone, cannot achieve flame retardancy unless the bromine content therein is usually 15% or more. However, higher bromine content leads to poor heat resistance, and CTI value is hard to reach 600V. Phosphorus-containing flame retardants, when used alone for flame retardancy, cannot achieve the UL94 V-0 level unless there is a higher phosphorus content. However, a too higher phosphorus content will result in the disadvantage of increased moisture absorption. The present invention discloses adding at the same time the bromine-containing and phosphorous-containing epoxy resins, adjusting the ratio thereof in the epoxy resin composition so as to make the bromine content be 5-12% and the phosphorus content be 0.2-1.5%, which not only makes the flame retardancy reach the UL94 V-0 level, but also has a higher heat resistance and can achieve a higher CTI value (CTI>600V) than CCL merely using bromine-containing epoxy resin flame retardant materials for flame retardancy, and has a lower moisture absorption and a longer solder dipping resistance time than CCL merely using phosphorus-containing epoxy resin flame retardant materials for flame retardancy.

In the present invention, the mixture of phosphorus-containing epoxy resin, bromine-containing epoxy resin and other epoxy resin is in an amount of 50-100 parts by weight, e.g. 50, 52, 55, 58, 60, 62, 65, 68, 70, 72, 75, 78, 80, 82, 85, 88, 90, 92, 95, 98, or 100 parts by weight.

In the present invention, the curing agent is in an amount of 1-50 parts by weight, e.g. 1, 5, 10, 15, 20, 22, 25, 28, 30, 32, 35, 38, 40, 42, 45, 48, or 50 parts by weight.

In the present invention, the curing accelerator is in an amount of 0.05-1.0 part by weight, e.g. 0.05, 0.08, 0.1, 0.2, 0.3, 0.4, 0.5, 0.6, 0.7, 0.8, 0.9, or 1.0 part by weight.

In the epoxy resin composition of the present invention, the bromine is in an amount of 5-12%, e.g. 5%, 5.5%, 6%, 6.5%, 7%, 7.5%, 8%, 8.5%, 9%, 9.5%, 10%, 10.5%, 11%, 11.5%, 12%, preferably 5-10%, more preferably 5-8%, of the weight sum of organic solids in the composition.

In the epoxy resin composition of the present invention, the phosphorus is in an amount of 0.2-1.5%, e.g. 0.2%, 0.3%, 0.4%, 0.5%, 0.6%, 0.7%, 0.8%, 0.9%, 1.0%, 1.1%, 1.2%, 1.3%, 1.4%, 1.5%, preferably 0.5-1.5%, more preferably 0.8-1.5%, of the weight sum of organic solids in the composition.

In the present invention, the bromine-containing epoxy resin is anyone selected from the group consisting of low bromine epoxy resin, high bromine epoxy resin, brominated isocyanate-modified epoxy resin and brominated bisphenol-A novolac epoxy resin, or a mixture of at least two selected therefrom.

In the present invention, said low bromine epoxy resin has a bromine content of 10%-25%; and said high bromine epoxy resin has a bromine of 40% or more.

In the present invention, the phosphorus-containing epoxy resin is a phosphorus-containing phenanthrene compound.

Preferably, the phosphorus-containing epoxy resin is anyone selected from the group consisting of the condensates of 9,10-dihydro-9-oxa-10-phosphaphenanthrene hydroquinone or 9,10-dihydro-9-oxa-10-phosphaphenanthrene naphthoquinone with bisphenol-A epoxy resin, o-cresol novolac epoxy resin, bisphenol-A novolac epoxy resin, phenol epoxy resin, dicyclopentadiene epoxy resin, MDI epoxy resin, bisphenol F epoxy resin and bisphenol S epoxy resin, or a mixture of at least two selected therefrom.

Since the current bromine-containing copper clad laminates mostly use reactive flame retardants, such as brominated epoxy, the bromine content in the bromine flame retardant system needs to be 15% or higher in order to achieve stable flame retardancy. A high bromine content will bring in great reductions of thermal resistance and CTI. In addition, if phosphorus-containing epoxy resin is used as the flame retardant, the phosphorus content needs to be close to 3% so as to make the flame retardancy achieve the UL94 V-0 level. Moreover, a high phosphorus content sharply increases the water absorption of the materials, so as to reduce the reliability of thereof.

The present invention discloses using low bromine epoxy resin, high bromine epoxy resin, brominated isocyanate-modified epoxy resin and brominated bisphenol-A novolac epoxy resin as bromine sources, in combination with phosphorus-containing phenanthrene compounds as phosphorus sources, to provide synergistic effect, so as to make the flame retardancy of the substrates achieve the UL94 V-0 level with bromine and phosphorus having a relatively lower content. Moreover, they could further improve the cohesiveness, processability and process operability of the substrates, achieve a CTI of 600V of and a lower water absorption, and reduce the dependence of the flame retardancy on bromine, so as to be more environmentally friendly. Moreover, phosphorus and bromine in the present invention both are connected to the polymer backbone. Thus, the composite materials can achieve a higher glass transition temperature as compared to the additive-introduction means of phosphorus and bromine.

In the present invention, said other epoxy resin is phosphorus- and bromine-free epoxy resin, and specifically is anyone selected from the group consisting of bisphenol-A epoxy resin, o-cresol novolac epoxy resin, bisphenol-A novolac epoxy resin, phenol epoxy resin, dicyclopentadiene epoxy resin, MDI epoxy resin, bisphenol F epoxy resin, bisphenol S epoxy resin, bisphenol F epoxy resin, tetrafunctional epoxy resin, naphthalene epoxy resin and biphenyl epoxy resin, or a mixture of at least two selected therefrom.

In the present invention, the curing agent is anyone selected from the group consisting of phenolic resin, aromatic diamine-based curing agent, dicyandiamide, aliphatic amine, acid anhydride, active polyester and cyanate, or a mixture of at least two selected therefrom.

Preferably, said phenolic resin is anyone selected from the group consisting of phenol novolac resin, bisphenol-A novolac resin, o-cresol novolac resin, triphenol novolac resin, naphthalene novolac resin, biphenyl novolac resin and dicyclopentadiene novolac resin, or a mixture of at least two selected therefrom.

Preferably, the aromatic diamine-based curing agent has the following chemical structural formula:

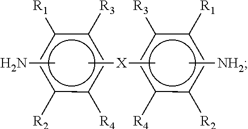

wherein X is selected from the group consisting of

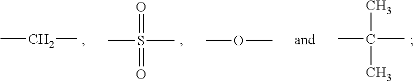

R₁, R₃ and R₄ are selected from the group consisting of H, —CH₃ and —C₂H₅; R₂ is selected from the group consisting of H, —CH₃ and —C₂H₅.

Preferably, the mole number of the active hydrogen H in the curing agent and the mole number of the epoxy group E in the epoxy resin satisfy the formula H/E=0.8-1.2.

In the present invention, said curing accelerator is anyone selected from the group consisting of imidazole curing accelerator, organic phosphine curing accelerator and tertiary amine curing accelerator, or a mixture of at least two selected therefrom.

Preferably, said imidazole curing accelerator is anyone selected from the group consisting of 2-methylimidazole, 2-methyl-4-ethylimidazole, 2-undecylimidazole, 2-phenylimidazole and 1-cyanoethyl-2-ethyl-4-methylimidazole, or a mixture of at least two selected therefrom.

Preferably, said organic phosphine curing accelerator is tributylphosphine and/or triphenyiphosphine.

Preferably, said tertiary amine curing accelerator is benzyl dimethyl amine

In the present invention, the amount of the curing accelerator shall not be excessive. If the amount is too large, the reaction will be too fast to be conducive to the process operations and material storage.

In the present invention, said epoxy resin composition further comprises a filler, preferably an inorganic filler.

Preferably, said filler is anyone selected from the group consisting of boehmite, aluminum hydroxide, barium sulfate, calcium fluoride, magnesium hydroxide, silica, glass powder, kaolin, talc powder, mica powder, aluminum oxide, zinc oxide, magnesium oxide, boron nitride, aluminum nitride and calcium carbonate, or a mixture of at least two selected therefrom.

Preferably, said filler has an average particle size of 0.3-20 μm;

Preferably, said filler is in an amount of, based on the sum of organic solids of all components in said epoxy resin composition being 100 parts by weight, from 20 to 200 parts by weight, e.g. 20, 30, 50, 60, 80, 100, 120, 140, 150, 180, or 200 parts by weight,

The present invention discloses further improving the CTI of the substrates by adding the fillers such as aluminum hydroxide, barium sulfate or boehmite and the like, to 600V or more.

In order to make said inorganic filler be homogeneously dispersed in the epoxy resin and improve the binding force between the resin and filler, an appropriate auxiliary agent may be added into said epoxy resin composition. The auxiliary agent used therein is an amino silane coupling agent or an epoxy silane coupling agent. Such coupling agent contains no heavy metals, and has no adverse effects on human health. The usage amount thereof is 0.5-2% by weight of the inorganic filler.

In the present invention, said epoxy resin composition further comprises a solvent, preferably an organic solvent.

Preferably, said solvent is anyone selected from the group consisting of N,N′-dimethyl-formamide, ethylene glycol ethyl ether, propylene glycol methyl ether, acetone, butanone, methanol, ethanol, benzene and toluene, or a mixture of at least two selected therefrom.

As to the epoxy resin composition of the present invention, a solvent may be used to adjust the viscosity. The aforesaid solvent can adjust the content of solid components in the epoxy resin composition to 40-80%.

In the second aspect, the present invention further provides a prepreg prepared by using the epoxy resin composition stated in the first aspect of the present invention, comprising a base material, and the epoxy resin composition attached thereon after impregnation and drying.

Preferably, said base material is selected from the group consisting of non-woven and woven glass fiber cloth.

In the third aspect, the present invention further provides a laminate comprising the prepreg stated in the second aspect of the present invention.

In the fourth aspect, the present invention further provides a printed circuit board, comprising the laminate stated in the third aspect of the present invention.

As compared to the prior art, the present invention has the following beneficial effects.

(1) In the epoxy resin composition of the present invention, a specific phosphorus-bromine ratio is used, which not only makes the flame retardancy reach the UL94 V-0 level, but also improves the CTI of the materials which may reach CTI>600V, while effectively controlling costs.
(2) The epoxy resin composition of the present invention has better heat resistance than pure bromine flame retardant system, and lower moisture absorption than pure phosphorus flame retardant system, i.e. solving the problems that pure bromine flame retardant has a worse thermal resistance, and pure phosphorus flame retardant has a high moisture absorption, and thus has excellent comprehensive performance.
(3) The prepregs and CCLs prepared by using the epoxy resin composition of the present invention have a high glass transition temperature, a high heat resistance, a high peeling strength, a high CTI and better processability, and are suitable for lead-free soldering.
(4) The present invention discloses further decreasing the dependence of the flame retardancy on bromine element, so as to be more environmentally friendly.

### EMBODIMENTS

The technical solution of the present invention is further stated by the following specific embodiments, but is not limited to these embodiments,

Those skilled in the art shall know that said examples are only used for understanding the present invention, and shall not be deemed as specific limitations to the present invention.

### Examples Process for Preparing CCLs

Epoxy resin, curing agent, filler and curing accelerator, together with organic solvent, were homogeneously mixed in a stirring and dispersing device. Said epoxy resin composition was pre-impregnated to non-woven or woven glass fiber cloth, and dried in a glue machine (120-180° C.) to prepare semi-cured prepregs for printed circuit boards.

Several sheets of prepreg above were stacked together. One side or both sides of the stacked sheets were laminated with copper foil, and then placed on a laminator at 120-200° C., hot-pressed into a form and prepared into a CCL for printed circuit board processing. Said copper foil can also be replaced with aluminum foil, silver foil or stainless steel foil.

As for CCLs prepared in said examples, performance tests were made for the glass transition temperature, CTI, flame retardancy, solder dipping resistance time, PCT water absorption, 5% thermal weight loss and drilling processability, and further described and stated in the following Examples 1-5 and Comparative Examples 1-7.

The components in the epoxy resin composition in Examples 1-5 and Comparative Examples 1-5 and contents thereof (parts by weight) are shown in Table 1, wherein the epoxy resin compositions in Table 1 are based on 100% of solid contents. The codes of each component and the corresponding component names are stated as follows.

(A) Epoxy resin
(A1) Brominated bisphenol-A epoxy resin: DER530A80, having an epoxy equivalent of 430 g/eq, from DOW Chemical;
(A2) brominated isocyanate-modified epoxy resin: DER592A80, having an epoxy equivalent of 360 g/eq, from DOW Chemical;
(A3) high bromine epoxy resin: EPICLON153-60M, having a bromine content of 48% and an epoxy equivalent of 380 g/eq, from DAINIPPON INK & CHEMICALS;
(A4) phosphorus-containing epoxy resin: GEBR521K70, having an epoxy equivalent of 540 g/eq, from Hongchang Resin;
(A5) tetrafunctional epoxy resin: 1031, having an epoxy equivalent of 210 g/eq, from Momentive;
(B) Curing agent
(B1) linear novolac resin: 2812, from Momentive;
(B2) aromatic diamine: 4,4-DDS, from Yinsheng Taiwan;

### (C) Filler

### (C1) Boehmite: Bengbu Xinyuan Quartz Material Limited Company;

(C2) Aluminum hydroxide: Albemarle Corporation;
(C3) Barium sulfate: Guizhou Redstar
(D) Curing accelerator: 2-E-4MI, Shikoku Chemicals;
(E) Organic solvent: butanone, from Dow Chemical.

The following methods are used to test the CCLs prepared in Examples 1-5 and Comparative Examples 1-7, and the test methods for each performance parameter are stated as follows.
(A) Glass transition temperature (Tg): on the basis of the differential scanning calorimetry (DSC), tested according to the DSC method as stipulated under IPC-TM-650 2.4.25.
(B) Comparative tracking index (CTI): tested according to the method as stipulated under GB/T 4207-84.
(C) Solder dipping resistance time: impregnating a double-sided copper foil plate having a size of 100×100 mm into a solder tank heated to 288° C., and recording the time from impregnation to delamination and popcorn of the plate.
(D) PCT water absorption: pre-drying the sample, weighing and cooking in a pressure cooker for 4 hours, and observing the mass change rate.
(E) 5% thermal weight loss: heating under the nitrogen atmosphere to 500° C. at a heating rate of 5° C./min, and recording the temperature at which the sample mass losses 5%.
(F) Drilling processability: stacking two plates having a thickness of 1.6 mm together, continuously drilling 5000 holes with a 0.3 mm drill at a drilling speed of 110 krpm and a falling speed of 33 mm/s, observing the cutting edge wear of the drill per 1000 holes, and determining the drilling processability according to the wear conditions.
(G) Flame retardancy: tested according to the method under UL 94.

The test results of the CCLs prepared in Examples 1-5 and Comparative Examples 1-7 are shown in Tables 2 and 3.

TABLE 1

| | | | | | | Comp. | Comp. | Comp. | Comp. | Comp. |
|---|---|---|---|---|---|---|---|---|---|---|
| | Example | Example | Example | Example | Example | Example | Example | Example | Example | Example |
| Materials | 1 | 2 | 3 | 4 | 5 | 1 | 2 | 3 | 4 | 5 |
| A1 | 60 | 60 | 33 | 60 | 0 | 90 | 50 | 0 | 45 | 0 |
| A2 | 0 | 0 | 0 | 0 | 60 | 0 | 0 | 0 | 0 | 0 |
| A3 | 0 | 0 | 0 | 0 | 0 | 0 | 0 | 0 | 21 | 27 |
| A4 | 7 | 25 | 67 | 25 | 25 | 0 | 0 | 90 | 7 | 42 |
| A5 | 14 | 10 | 10 | 10 | 10 | 10 | 20 | 10 | 14 | 6 |
| B1 | 17 | 20 | 20 | 20 | 20 | 20 | 19 | 20 | 17 | 10.2 |
| B2 | 3 | 2.5 | 4 | 2.5 | 2.5 | 4 | 2 | 2 | 3 | 2.4 |
| D | 0.05 | 0.05 | 0.05 | 0.05 | 0.05 | 0.05 | 0.06 | 0.06 | 0.05 | 0.03 |
| C1 | 30 | 30 | 30 | 0 | 30 | 30 | 30 | 30 | 30 | 18 |
| C3 | 20 | 20 | 20 | 0 | 20 | 20 | 20 | 20 | 20 | 12 |
| C2 | 10 | 10 | 10 | 0 | 10 | 10 | 10 | 10 | 10 | 6 |
| E | 40 | 40 | 40 | 20 | 40 | 40 | 40 | 40 | 35 | 18 |
| Phosphorus | 0.2% | 0.64% | 1.5% | 0.64% | 0.64% | 0.00% | 0.00% | 2.21% | 0.2% | 1.7% |
| content % | | | | | | | | | | |
| Bromine | 12.0% | 10.2% | 5.0% | 10.2% | 9% | 14.5% | 11.0% | 0.0% | 16.5% | 12.0% |
| content % | | | | | | | | | | |

The preparation methods and material manufacturers in Comparative Examples 6 and 7 are listed as follows.

Comparative Example 6: 23 parts by weight of synthetic rubber (trade name Nipol 1072CGX, from ZEON), 25 parts by weight of brominated epoxy (trade name DER530A80, from DOW), 21 parts by weight of high bromine epoxy (trade name EPICLON 153-60M, from DAINIPPON INK & CHEMICALS), 25 parts by weight of biphenyl epoxy (trade name NC3000H, from Nippon Kayaku), 0.2 part by weight of 2E4MI (from Shikoku Chemicals), 10.1 parts by weight of aromatic diamine: 4,4-DDS (from Yinsheng Taiwan), 20 parts by weight of phenoxyphosphazene (SPB-100, having a phosphorus content of 13.4%, from Albemarle Corporation), 15 parts by weight of aluminum hydroxide (from Albemarle Corporation), 31 parts by weight of boehmite (from to Bengbu Xinyuan Quartz Material Limited Company), 8 parts by weight of barium sulfate(Guizhou Redstar), solvent MEK to adjust the solid content to 66%.

Calculation: having a bromine content of 12.0% and a phosphorus content of 0.2%; the filler proportion and ratio were the same as those in Example 1.

Comparative Example 7: 33 parts by weight of nitrile rubber-modified epoxy (SC-024, from SHIN-A), 67 parts by weight of brominated epoxy resin (DEBR530A80, from DOW), 3 parts by weight of dicyandiamide, 0.02 part by weight of 2-methylimidazole, 6 parts by weight of tetrabromobisphenol A, 31 parts by weight of phosphorus-containing phenolic aldehyde (LC950, from SHIN-A), 17 parts by weight of aluminum hydroxide (from Albemarle Corporation), 34 parts by weight of boehmite (from Bengbu Xinyuan Quartz Material Limited Company), 9 parts by weight of barium sulfate (from Guizhou Redstar), solvent MEK to adjust the solid content to 66%.

Calculation: having a bromine content of 12.0% and a phosphorus content of 0.2%; the filler proportion and ratio were the same as those in Example 1.

TABLE 2

| | Example | Example | Example | Example | Example | Comp. | Comp. |
|---|---|---|---|---|---|---|---|
| Test items | 1 | 2 | 3 | 4 | 5 | Example 1 | Example 2 |
| Tg (DSC) (° C.) | 142 | 141 | 144 | 140 | 149 | 133 | 140 |
| CTI (V) | 600 | 600 | 600 | 175 | 600 | 500 | 600 |
| Solder dipping | >600 s | >600 s | >600 s | >600 s | >600 s | <400 s | >600 s |
| resistance time | | | | | | | |
| PCT water | 0.19 | 0.21 | 0.25 | 0.22 | 0.24 | 0.20 | 0.21 |
| absorption % | | | | | | | |
| Td 5% | 360 | 362 | 366 | 360 | 358 | 350 | 361 |
| Flammability | V-0 | V-0 | V-0 | V-0 | V-0 | V-0 | V-1 |
| Drilling | Good | Good | Good | Good | Good | Good | Good |

TABLE 3

| | Comp. | Comp. | | Comp. | | Comp. | | Comp. | |
|---|---|---|---|---|---|---|---|---|---|
| | Example | Example | | Example | | Example | | Example | |
| Test items | 3 | 4 | | 5 | | 6 | | 7 | |
| Tg (DSC) (° C.) | 134 | 141 | | 139 | | 112 | | 131 | |
| CTI (V) | 600 | 300 | V | 600 | V | 525 | V | 550 | V |
| Solder dipping | >600 s | <400 | s | <300 | s | <300 | s | <300 | s |

| | | | | | |
|---|---|---|---|---|---|
| resistance time | | | | | |
| PCT water | 0.35 | 0.22 | 0.33 | 0.55 | 0.58 |
| absorption % | | | | | |
| Td 5% | 367 | 352 | 359 | 348 | 344 |
| Flammability | V-0 | V-0 | V-0 | V-0 | V-0 |
| Drilling | General | General | General | Good | Good |

According to Tables 1-3, the followings can be seen.

(1) According to Examples 1-5, it can be seen that the epoxy resin compositions in Examples 1-5 all could achieve the flame retardancy of UL 94 V-0 level, and have a solder dipping resistance time of greater than 600 s and a better drilling processability,
(2) According to Examples 1-5, it could be seen that the epoxy resin compositions in Examples 1-3 all had a Comparative Tracking Index (CTI) of 600V, while the epoxy resin composition in Example 4 had a Comparative Tracking Index (CTI) of only 175V, which showed that the addition of a suitable amount of filler into the epoxy resin composition could make the substrate have a high CTI.
(3) As compared to Comparative Example 3, the POT water absorptions in Examples 1-5 were better than that in Comparative Example 3. Since only phosphorus-containing epoxy resin was used in Comparative Example 3, and the phosphorus content was as high as 2.21%, the moisture absorption thereof was increased. In Examples 1-5, phosphorus-containing epoxy resin and bromine-containing epoxy resin were both used, and low moisture absorption could be achieved when the phosphorus content was only 0.2%-1.5%, which showed that the substrates could have a low water absorption when phosphorus-containing epoxy resin and bromine-containing epoxy resin were used in combination.
(4) As compared to Comparative Example 2, Examples 2-5 disclosed that phosphorus and bromine were used synergistically for flame retardancy, and only less than 11% of bromine was needed to achieve the UL94 V-0 level. Comparative Example 2 disclosed only introducing bromine for flame retardancy. Although the bromine content reached 11%, it could not achieve the UL94 V-0 level yet.
(5) As compared to Comparative Example 1, Examples 1-5 disclosed that, since phosphorus and bromine were used synergistically for flame retardancy, only 12% or less of bromine was needed to achieve the UL94 V-0 level. Thus, Examples 1-5 had better chemical heat resistance than Comparative Example 1, i.e. 5% thermal weight loss temperature being 10° C. higher than that in Comparative Example 1, and longer solder dipping resistance time.
(6) Comparative Examples 4 and 5 respectively disclosed the circumstances in which the bromine content and phosphorus content were not within the range of the present invention. It could be seen that, when the bromine content was 16.5%, Td and soldering dipper resistance time were obviously lower than those in Example 1, and CTI could not reach 600V, although the flame retardancy could be achieved. When the phosphorus content was 1.7%, the materials were also flame retardant although the CTI reached 600V. However, the soldering dipping resistance time was reduced to 300 s or less, and the PCT water absorption reached higher than 0.3%.
(7) Comparative Examples 6 and 7 respectively disclosed the resin compositions in CN 101808466A and CN 101892027A could not reach a CTI of 600V when having the same bromine content, phosphorus content and filler system as the present invention. Moreover, the water absorption was obviously higher than that of the present invention, and the soldering dipping resistance time could not reach 300 s. The present invention, however, showed a better thermal shock resistance. By comparing the present invention with Comparative Example 6, it can be found that the reactive phosphorus- and bromine-introduction way can have no effect on the glass transition temperature of the materials. Although phosphorus-containing phenolic aldehyde in Comparative Example 7 can participate in the reaction, the reactivity itself is poor, and it is hard to completely graft to the polymer backbone. Thus it will affect the Tg of the plates.

In conclusion, the epoxy resin composition of the present invention has a greatly increased heat resistance as compared to pure bromine flame retardant system, and has a CTI of 600V or higher after the filler such as boehmite is added. As compared to pure phosphorus flame retardant system, the epoxy resin composition has a lower water absorption, a better drilling processability and a better flame retardancy. The prepregs and CCLs prepared from said epoxy resin composition have excellent CTI property, so as to significantly improve the adaptability of PCBs in harsh environments. Meanwhile, relatively higher thermal resistance and longer solder dipping resistance time make the epoxy resin composition be suitable for the needs of lead-free soldering. Moreover, the present invention can further reduce the dependence of flame retardancy on bromine, so as to be more environmentally friendly.

The applicant claims that the present invention describes the detailed process of the present invention, but the present invention is not limited to the detailed process of the present invention. That is to say, it does not mean that the present invention shall be carried out with respect to the above-described detailed process of the present invention. Those skilled in the art shall know that any improvements to the present invention, equivalent replacements of the raw materials of the present invention, additions of auxiliary, selections of any specific ways all fall within the protection scope and disclosure scope of the present invention.

1.-10. (canceled)

11. An epoxy resin composition, characterized in comprising, based on the weight parts of organic solids,
(A) from 50 to 100 parts by weight of a mixture of phosphorus-containing epoxy resin, bromine-containing epoxy resin and other epoxy resin,
(B) from 1 to 50 parts by weight of a curing agent,
(C) from 0.05 to 1.0 part by weight of a curing accelerator,
wherein the bromine in the epoxy resin composition is in an amount of 5-12% of the weight sum of organic solids in the composition; the phosphorus in the epoxy resin composition is in an amount of 0.2-1.5% of the weight sum of organic solids in the composition.

12. The epoxy resin composition claimed in claim 11, wherein the bromine in the epoxy resin composition is in an amount of 5-10%, of the weight sum of organic solids in the composition; and wherein the phosphorus in the epoxy resin composition is in an amount of 0.5-1.5%, of the weight sum of organic solids in the composition.

13. The epoxy resin composition claimed in claim 11, wherein the bromine-containing epoxy resin comprises at least one member selected from the group consisting of low bromine epoxy resin, high bromine epoxy resin, brominated isocyanate-modified epoxy resin and brominated bisphenol-A novolac epoxy resin.

14. The epoxy resin composition claimed in claim 12, wherein the low bromine epoxy resin has a bromine content of 10%-25%; and the high bromine epoxy resin has a bromine of 40% or more.

15. The epoxy resin composition claimed in claim 11, wherein the phosphorus-containing epoxy resin is a phosphorus-containing phenanthrene compound.

16. The epoxy resin composition claimed in claim 11, wherein the phosphorus-containing epoxy resin comprises at least one member selected from the group consisting of the condensates of 9,10-dihydro-9-oxo-10-phosphaphenanthrene hydroquinone or 9,10-dihydro-9-oxo-10-phosphaphenanthrene naphthoquinone with bisphenol-A epoxy resin, o-cresol novolac epoxy resin, bisphenol-A novolac epoxy resin, phenol epoxy resin, dicyclopentadiene epoxy resin, MDI epoxy resin, bisphenol F epoxy resin and bisphenol S epoxy resin.

17. The epoxy resin composition claimed in claim 11, wherein said other epoxy resin is phosphorus- and bromine-free epoxy resin, and specifically is anyone selected from the group consisting of bisphenol-A epoxy resin, o-cresol novolac epoxy resin, bisphenol-A novolac epoxy resin, phenol epoxy resin, dicyclopentadiene epoxy resin, MDI epoxy resin, bisphenol F epoxy resin, bisphenol S epoxy resin, tetrafunctional epoxy resin, naphthalene epoxy resin and biphenyl epoxy resin, or a mixture of at least two selected therefrom.

18. The epoxy resin composition claimed in claim 11, wherein the curing agent comprises at least one member selected from the group consisting of phenolic resin, aromatic diamine-based curing agent, dicyandiamide, aliphatic amine, acid anhydride, active polyester and cyanate.

19. The epoxy resin composition claimed in claim 18, wherein the phenolic resin comprises at least one member selected from the group consisting of phenol novolac resin, bisphenol-A novolac resin, o-cresol novolac resin, triphenol novolac resin, naphthalene novolac resin, biphenyl novolac resin and dicyclopentadiene novolac resin.

20. The epoxy resin composition claimed in claim 18, wherein the aromatic diamine-based curing agent has the following chemical structural formula: 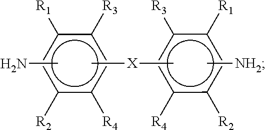
wherein X is selected from the group consisting of —CH₂—, 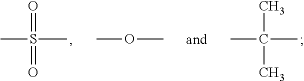
R₁, R₃ and R₄ are selected from the group consisting of H, —CH₃ and —C₂H₅; R₂ is selected from the group consisting of H, —CH₃ and —C₂H₅.

21. The epoxy resin composition claimed in claim 11, wherein the mole number of the active hydrogen H in the curing agent and the mole number of the epoxy group E in the epoxy resin satisfy the formula H/E=0.8-1.2.

22. The epoxy resin composition claimed in claim 11, wherein the curing accelerator comprises at least one member selected from the group consisting of imidazole curing accelerator, organic phosphine curing accelerator and tertiary amine curing accelerator.

23. The epoxy resin composition claimed in claim 22, wherein the imidazole curing accelerator comprises at least one member selected from the group consisting of 2-methylimidazole, 2-methyl-4-ethylimidazole, 2-undecylimidazole, 2-phenylimidazole and 1-cyanoethyl-2-ethyl-4-methylimidazole;
the organic phosphine curing accelerator is tributylphosphine and/or triphenylphosphine;
the tertiary amine curing accelerator is benzyl dimethyl amine.

24. The epoxy resin composition claimed in claim 11, wherein the epoxy resin composition further comprises a filler.

25. The epoxy resin composition claimed in claim 24, wherein the filler comprises at least one member selected from the group consisting of boehmite, aluminum hydroxide, barium sulfate, calcium fluoride, magnesium hydroxide, silica, glass powder, kaolin, talc powder, mica powder, aluminum oxide, zinc oxide, magnesium oxide, boron nitride, aluminum nitride and calcium carbonate;
the filler has an average particle size of 0.3-20 μm;
the filler is in an amount of, based on the sum of organic solids of all components in the epoxy resin composition being 100 parts by weight, from 20 to 100 parts by weight.

26. The epoxy resin composition claimed in claim 11, wherein the epoxy resin composition further comprises a solvent.

27. The epoxy resin composition claimed in claim 26, wherein the solvent comprises at least one member from the group consisting of N,N′-dimethyl-formamide, ethylene glycol ethyl ether, propylene glycol methyl ether, acetone, butanone, methanol, ethanol, benzene and toluene.

28. A prepreg prepared by using the epoxy resin composition claimed in claim 11, comprising a base material, and wherein the epoxy resin composition attached thereon after impregnation and drying.

29. A laminate comprising the prepreg claimed in claim 28.

30. A printed circuit board comprising the laminate claimed in claim 29.
